(19) United States
(12) Patent Application Publication
(10) Pub. No.: US 2026/0059695 A1
(43) Pub. Date: Feb. 26, 2026

(54) COOLING DEVICE AND ELECTRONIC APPARATUS

(71) Applicant: Fujitsu Limited, Kawasaki-shi (JP)

(72) Inventors: Akira Nakayama, Kawasaki (JP); Hiroyuki Kubo, Kawasaki (JP); Yasuhisa Kanemaru, Fukuoka (JP); Mitsuru Etou, Fukuoka (JP); Takashi Shirakami, Kawasaki (JP)

(73) Assignee: Fujitsu Limited, Kawasaki-shi (JP)

(21) Appl. No.: 19/058,604

(22) Filed: Feb. 20, 2025

(30) Foreign Application Priority Data
Mar. 15, 2024 (JP) 2024-041678

(51) Int. Cl. H05K 7/20

(52) U.S. Cl. CPC H05K 7/20254; H05K 7/20263; H05K 7/20272

(57) ABSTRACT

A cooling device includes a cold plate that includes a plurality of flow paths through which a refrigerant flows, and cools a heat generating component with the refrigerant, one ends of the flow paths being positioned near one side wall in a first direction, and the other ends thereof being positioned near the other side wall, a radiator that is provided on the cold plate and cools the refrigerant to be discharged from the flow paths, and a first manifold and a second manifold that are provided with the radiator interposed therebetween in the first direction, wherein the first manifold allows the refrigerant to flow into the one ends of the flow paths and allows the refrigerant having passed through the radiator to flow therein, and the second manifold allows the refrigerant discharged from the other ends of the flow paths to flow into the radiator.

### CROSS-REFERENCE TO RELATED APPLICATION

This application is based upon and claims the benefit of priority of the prior Japanese Patent Application No. 2024-041678 filed on Mar. 15, 2024, the entire contents of which are incorporated herein by reference.

### FIELD

A certain aspect of the embodiments is related to a cooling device and an electronic apparatus.

### BACKGROUND

Electronic components suffer from deterioration of characteristics and reduction of life due to temperature rise caused by heat generation. Various cooling devices for cooling electronic components are known (for example, Patent Document 1: Japanese Laid-open Patent Publication No. 8-227954, Patent Document 2: Japanese Laid-open Patent Publication No. 8-279578, Patent Document 3: Japanese Laid-open Patent Publication No. 10-335551, and Patent Document 4: U.S. Unexamined Patent Application Publication No. 2016/0201993).

### SUMMARY

According to an aspect of the present disclosure, there is provided a cooling device including: a cold plate that includes a plurality of flow paths through which a refrigerant flows, and cools a heat generating component with the refrigerant, one ends of the plurality of flow paths being positioned near one side wall of a pair of side walls in a first direction, and the other ends thereof being positioned near the other side wall; a radiator that is provided on the cold plate and cools the refrigerant to be discharged from the plurality of flow paths; and a first manifold and a second manifold that are provided with the radiator interposed therebetween in the first direction; wherein the first manifold allows the refrigerant to flow into the one ends of the plurality of flow paths and allows the refrigerant having passed through the radiator to flow therein, and the second manifold allows the refrigerant discharged from the other ends of the plurality of flow paths to flow into the radiator.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of a cooling device according to a first embodiment.

FIG. 2 is an exploded perspective view of the cooling device according to the first embodiment.

FIGS. 3A and 3B are perspective views illustrating the flow of a refrigerant in the cooling device according to the first embodiment.

FIG. 4 is a perspective view illustrating the flow of the refrigerant in the cooling device according to the first embodiment.

FIG. 5A is a plan view of an electronic apparatus including a cooling device according to a first comparative example.

FIG. 5B is a plan view of a substrate on which a cooling device according to the first comparative example 1 is mounted.

FIG. 5C is a cross-sectional view taken along a line A-A in FIG. 5A.

FIG. 6A is a plan view of an electronic apparatus including a cooling device according to a second comparative example.

FIG. 6B is a plan view of a substrate on which the cooling device according to the second comparative example is mounted.

FIG. 6C is a cross-sectional view taken along a line A-A in FIG. 6A.

FIG. 7A is a plan view of an electronic apparatus including the cooling device according to the first embodiment.

FIG. 7B is a cross-sectional view taken along a line A-A in FIG. 7A.

FIGS. 8A and 8B are plan views of a substrate on which the cooling device according to the first embodiment is mounted.

FIGS. 9A and 9B are perspective views illustrating the flow of a refrigerant in a cooling device according to a first modification of the first embodiment.

FIGS. 10A and 10B are perspective views illustrating the flow of a refrigerant in a cooling device according to a second modification of the first embodiment.

FIGS. 11A and 11B are perspective views of models 1 and 2 used in simulation, respectively.

FIG. 12A is a perspective view of a cold plate of a cooling device according to a second embodiment.

FIG. 12B is a cross-sectional view taken along a line A-A in FIG. 12A.

FIG. 13 is an exploded perspective view of an insertion member, a pressing member, and an elastic member according to the second embodiment.

FIG. 14A is a cross-sectional view illustrating a problem occurring in the cooling device according to the second comparative example.

FIG. 14B is a cross-sectional view illustrating an effect of the cooling device according to the second embodiment.

FIG. 15A is a perspective view of a cooling device according to a third embodiment.

FIG. 15B is a side view of the cooling device as viewed from a direction A in FIG. 15A.

FIG. 16A is a plan view of a substrate on which a cooling device according to a fourth embodiment is mounted.

FIG. 16B is a cross-sectional view taken along a line A-A in FIG. 16A.

FIG. 17 is a perspective view of a cooling device according to a fifth embodiment.

### DESCRIPTION OF EMBODIMENTS

There is a cooling device including a cold plate for cooling an electronic component by flowing a refrigerant, a radiator for cooling the refrigerant flowing through the cold plate by heat exchange with air, and a pipe for connecting the cold plate and the radiator. In this cooling device, the flow of air passing through the radiator is obstructed by the piping provided on the cold plate, and the cooling performance may not be sufficient.

In one aspect, an object of the present disclosure is to improve cooling performance.

Hereinafter, embodiments of the present invention will be described with reference to the drawings.

### First Embodiment

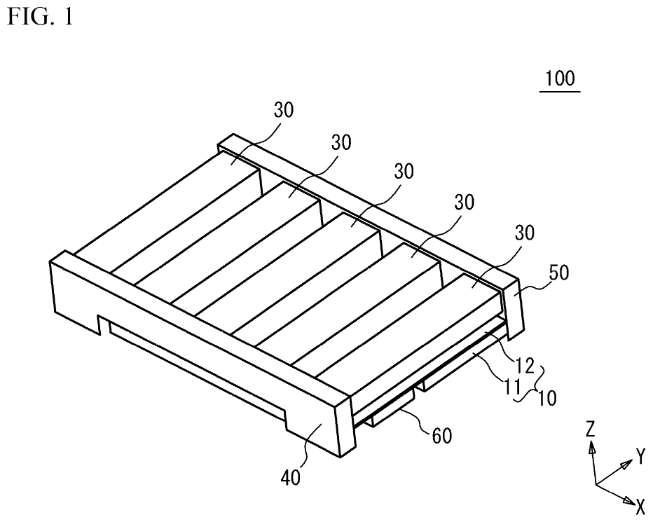

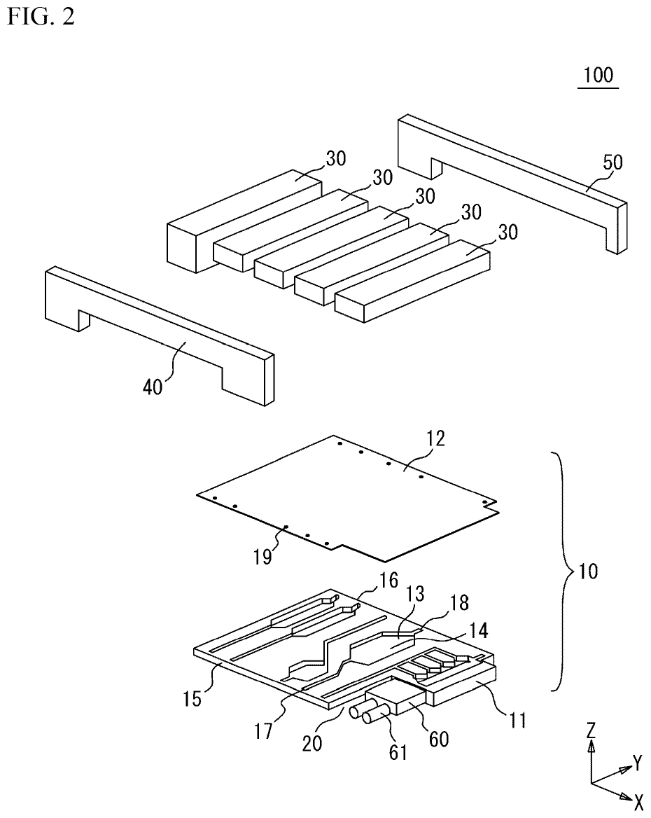

FIG. 1 is a perspective view of a cooling device 100 according to a first embodiment. FIG. 2 is an exploded perspective view of the cooling device 100 according to the first embodiment. As illustrated in FIGS. 1 and 2, the cooling device 100 according to the first embodiment includes a cold plate 10, one or a plurality of radiators 30, a first manifold 40, a second manifold 50, and a pump 60. Directions perpendicular to each other in a plane direction of the cold plate 10 are defined as an X-axis direction and a Y-axis direction. A thickness direction of the cold plate 10 is defined as a Z-axis direction.

The cold plate 10 includes a lower member 11, and an upper member 12 which is in contact with an upper surface of the lower member 11 and covers the upper surface of the lower member 11. A plurality of recesses 13 are provided in the upper surface of the lower member 11. The recesses 13 serve as flow paths 14 through which a refrigerant flow. The coolant is, for example, a cooling liquid such as cooling water. One ends 17 of the flow paths 14 are provided in the vicinity of a side wall 15 in the side walls 15 and 16 of the cold plate 10 facing each other in the Y-axis direction, and the other ends 18 of the flow paths 14 are provided in the vicinity of the other side wall 16. The upper member 12 has through holes 19 penetrating the upper member 12 at positions corresponding to the one ends 17 and the other ends 18 of the flow paths 14. The cold plate 10 is formed of a metal such as copper, aluminum, or stainless steel.

At least one of the plurality of radiators 30 is provided on the cold plate 10 so as to overlap the cold plate 10. The radiator 30 has a substantially rectangular parallelepiped shape whose longitudinal direction is the Y-axis direction and whose transverse direction is the X-axis direction. The plurality of radiators 30 are arranged in the X-axis direction. The length of the radiator 30 in the Y-axis direction is substantially equal to a distance between the side walls 15 and 16 of the cold plate 10. The radiator 30 has a function of cooling the refrigerant flowing through the flow path 14 of the cold plate 10 by heat exchange with air.

The first manifold 40 and the second manifold 50 are provided with the plurality of radiators 30 interposed therebetween in the Y-axis direction. The first manifold 40 is in contact with one end of the plurality of radiators 30, and the second manifold 50 is in contact with the other end of the plurality of radiators 30. The plurality of radiators 30 are supported by the first manifold 40 and the second manifold 50. The first manifold 40 and the second manifold 50 are formed of a metal such as copper or stainless steel, or a resin.

The pump 60 is disposed in a notch 20 provided in the lower member 11 of the cold plate 10. The pump 60 and the first manifold 40 are connected by pipes 61.

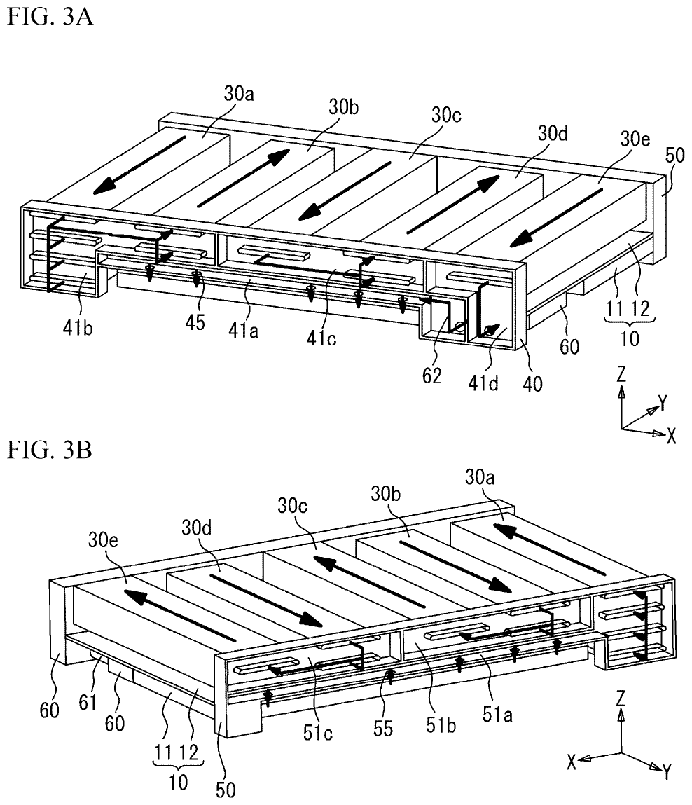

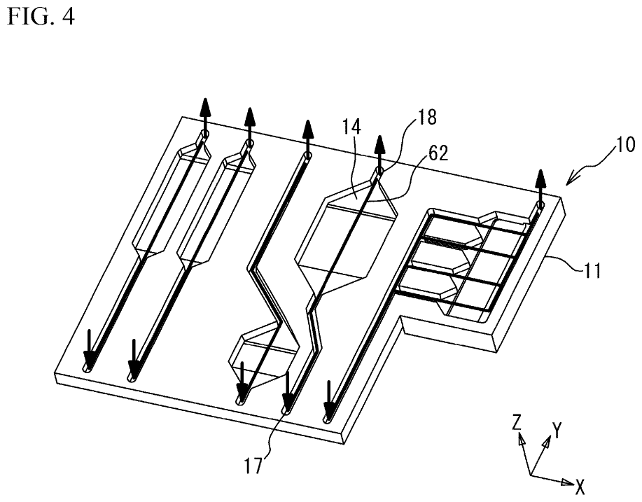

FIGS. 3A, 3B, and 4 are perspective views illustrating the flow of a refrigerant 62 in the cooling device 100 according to the first embodiment. FIG. 3A is a perspective view of the cooling device 100 according to the first embodiment as viewed from a −Y direction, and FIG. 3B is a perspective view of the cooling device 100 according to the first embodiment as viewed from a +Y direction. FIG. 4 is a perspective view of the lower member 11 of the cold plate 10. FIGS. 3A and 3B illustrate the interior of the first manifold 40 and the second manifold 50, respectively. The plurality of radiators 30 are arranged in the order of radiators 30a, 30b, 30c, 30d, and 30e from a −X direction to a +X direction.

As illustrated in FIG. 3A, the interior of the first manifold 40 is divided into a space 41a, a space 41b, a space 41c, and a space 41d. As illustrated in FIG. 3B, the interior of the second manifold 50 is divided into a space 51a, a space 51b, and a space 51c. The refrigerant 62 (illustrated by arrows) discharged from the pump 60 flows into the space 41a of the first manifold 40 through the pipe 61. The space 41a is provided with a plurality of through holes 45 communicating with the one ends 17 of the plurality of flow paths 14 of the cold plate 10. That is, the through holes 45 penetrate the first manifold 40 at positions corresponding to the through holes 19 provided in the upper member 12 of the cold plate 10 in FIG. 2. Therefore, the refrigerant 62 flows from the space 41a of the first manifold 40 to the one ends 17 of the plurality of flow paths 14 through the plurality of through holes 45 as illustrated in FIG. 4.

A plurality of through holes 55 communicating with the other ends 18 of the plurality of flow paths 14 of the cold plate 10 are provided in the space 51a of the second manifold 50. That is, the through holes 55 penetrate the second manifold 50 at positions corresponding to the through holes 19 provided in the upper member 12 of the cold plate 10 in FIG. 2. Therefore, the refrigerant 62 flowing through the plurality of flow paths 14 of the cold plate 10 flows into the space 51a of the second manifold 50 from the other ends 18 of the plurality of flow paths 14 through the through holes 55. One end of the pipe (tube) through which the refrigerant in the radiator 30a flows is connected to the space 51a. The other end of the pipe of the radiator 30a is connected to the space 41b of the first manifold 40. Therefore, the refrigerant 62 flows from the space 51a of the second manifold 50 in the −Y direction through the radiator 30a and flows into the space 41b of the first manifold 40.

One end of the pipe of the radiator 30b is further connected to the space 41b of the first manifold 40. The other end of the pipe of the radiator 30b is connected to the space 51b of the second manifold 50. Therefore, the refrigerant 62 flows from the space 41b of the first manifold 40 toward the +Y direction through the radiator 30b and flows into the space 51b of the second manifold 50. One end of the pipe of the radiator 30c is further connected to the space 51b. The other end of the pipe of the radiator 30c is connected to the space 41c of the first manifold 40. Therefore, the refrigerant 62 flows from the space 51b of the second manifold 50 in the −Y direction through the radiator 30c and flows into the space 41c of the first manifold 40.

One end of the pipe of the radiator 30d is further connected to the space 41c of the first manifold 40. The other end of the pipe of the radiator 30d is connected to the space 51c of the second manifold 50. Therefore, the refrigerant 62 flows from the space 41c of the first manifold 40 toward the +Y direction in the radiator 30d and flows into the space 51c of the second manifold 50. One end of the pipe of the radiator 30e is further connected to the space 51c. The other end of the pipe of the radiator 30e is connected to the space 41d of the first manifold 40. Therefore, the refrigerant 62 flows from the space 51c of the second manifold 50 toward the −Y direction through the radiator 30e and flows into the space 41d of the first manifold 40.

The refrigerant 62 flowing into the space 41d is sucked into the pump 60 through the pipe 61. The refrigerant 62 sucked into the pump 60 is discharged from the pump 60 again and flows into the space 41a of the first manifold 40 through the pipe 61. In this manner, the refrigerant 62 circulates between the first manifold 40, the cold plate 10, the second manifold 50, and the plurality of radiators 30.

### Comparative Example

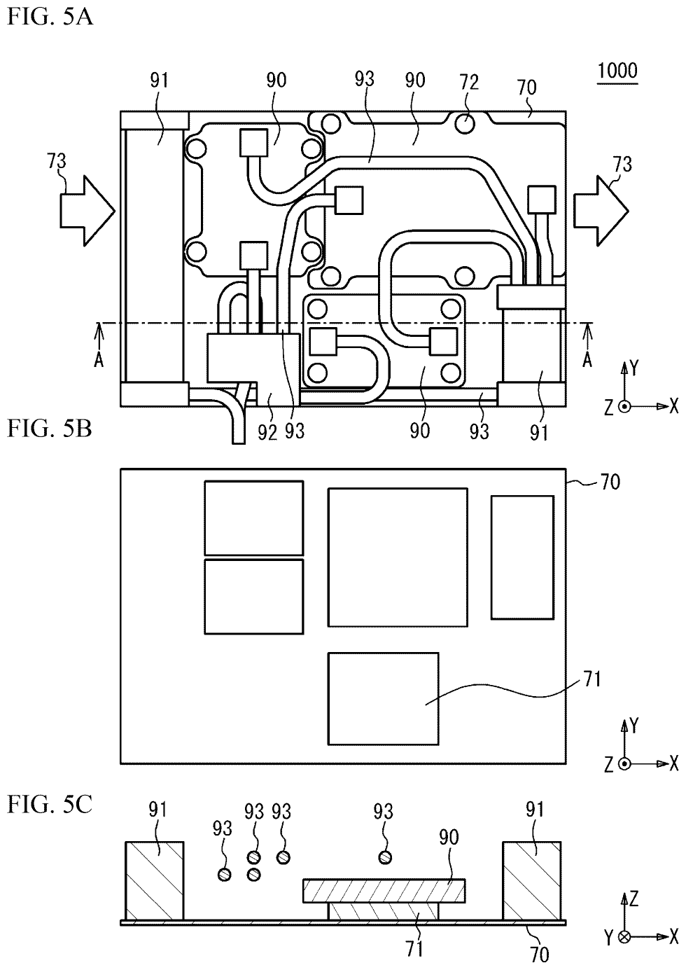

FIG. 5A is a plan view of an electronic apparatus 1000 including a cooling device according to a first comparative example, FIG. 5B is a plan view of a substrate 70 on which a cooling device according to a first comparative example is mounted, and FIG. 5C is a cross-sectional view taken along a line A-A in FIG. 5A. FIG. 5B illustrates only electronic components 71 provided on the substrate 70. As illustrated in FIGS. 5A to 5C, the cooling device according to the first comparative example includes a plurality of cold plates 90, a plurality of radiators 91, and a manifold 92. Pipes 93 are connected between the manifold 92 and the cold plate 90, between the cold plate 90 and the radiator 91, and between two radiators 91. As a result, the refrigerant supplied from the pump (not illustrated) to the manifold 92 flows through the pipes 93 to the cold plate 90 and the radiator 91.

The cold plate 90, the radiator 91 and the manifold 92 are fixed to the base plate 70 by fixing members 72 such as screws. The substrate 70 is, for example, a printed circuit board. One or more electronic components 71 are provided between the substrate 70 and each of the cold plates 90. The electronic component 71 is cooled by the refrigerant flowing inside the cold plate 90.

In the first comparative example, the pipe 93 is provided above the cold plate 90. Therefore, the flow of wind (air) 73 passing through the radiator 91 is obstructed by the pipe 93, and the cooling effect of the refrigerant by the radiator 91 is reduced. Therefore, the cooling performance for cooling the electronic component 71 is reduced.

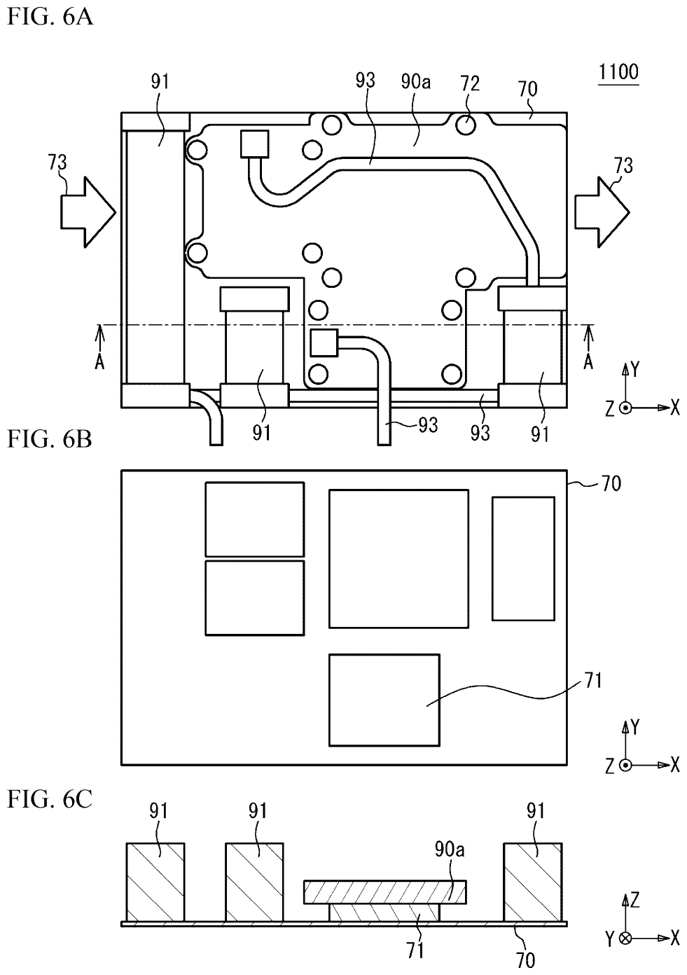

FIG. 6A is a plan view of an electronic apparatus 1100 including a cooling device according to a second comparative example, FIG. 6B is a plan view of the substrate 70 on which the cooling device according to the second comparative example is mounted, and FIG. 6C is a cross-sectional view taken along a line A-A in FIG. 6A. As illustrated in FIGS. 6A to 6C, the second comparative example differs from the first comparative example in that an integrated cold plate 90a in which the plurality of cold plates 90 are integrated into one plate.

In the second comparative example, the pipes 93 are provided to connect between the cold plate 90a and the radiator 91 and between the two radiators 91. Therefore, although the number of the pipes 93 is reduced as compared with the first comparative example, the flow of the wind 73 passing through the radiator 91 is sometimes obstructed by the pipes 93. Therefore, the cooling effect of the radiator 91 on the refrigerant is reduced, and the cooling performance for cooling the electronic component 71 is reduced.

### Effect of First Embodiment

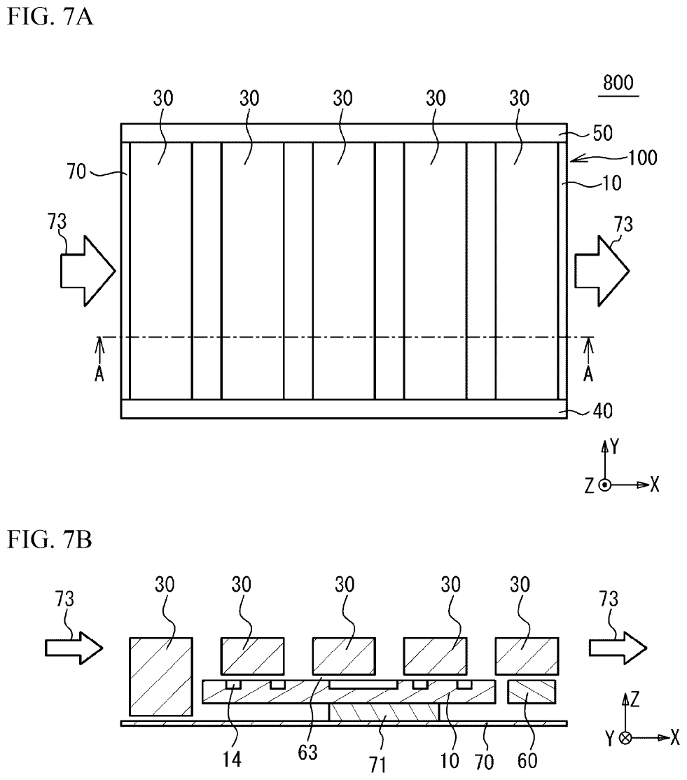

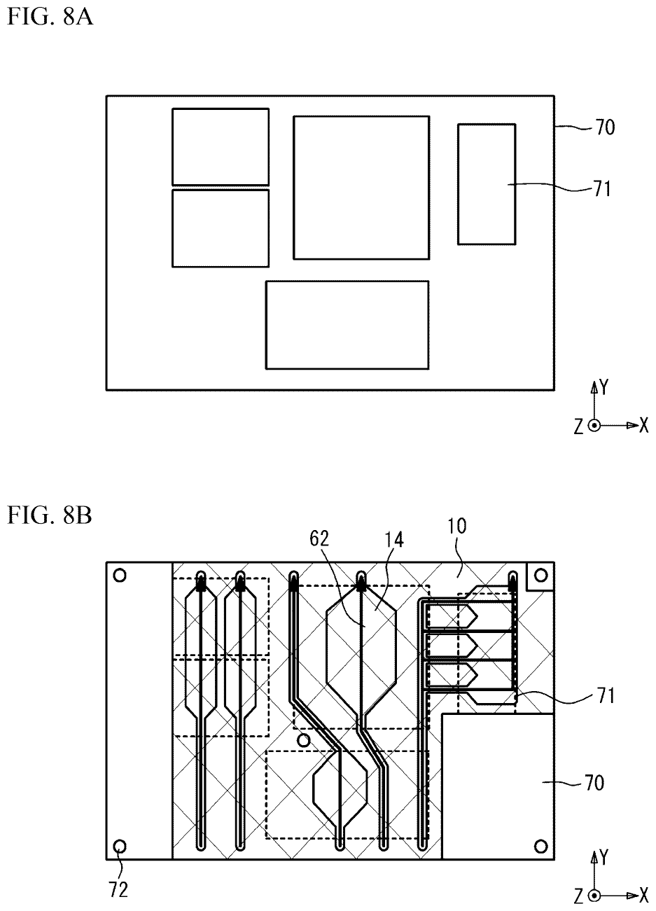

FIG. 7A is a plan view of an electronic apparatus 800 including the cooling device 100 according to the first embodiment, and FIG. 7B is a cross-sectional view taken along a line A-A in FIG. 7A. FIGS. 8A and 8B are plan views of the substrate 70 on which the cooling device 100 according to the first embodiment is mounted. FIG. 8A illustrates only the electronic component 71 provided on the substrate 70, and FIG. 8B illustrates the electronic component 71, the cold plate 10, and the fixing members 72, and the cold plate 10 is hatched for the sake of clarity of the drawing. As illustrated in FIGS. 7A to 8B, the cooling device 100 is provided on the substrate 70. The cold plate 10, the first manifold 40 and the second manifold 50 are fixed to the base plate 70 by the fixing members 72. The plurality of electronic components 71 are provided between the substrate 70 and the cold plate 10. The electronic component 71 is cooled by the refrigerant 62 flowing through the flow path 14 of the cold plate 10. Since the radiator 30 is supported by the first manifold 40 and the second manifold 50, the radiator 30 is not in contact with the cold plate 10, and a gap 63 is formed between the radiator 30 and the cold plate 10.

In the first embodiment, the pipe is not provided above the cold plate 10 as compared with the first and the second comparative examples. Therefore, the flow of the wind 73 passing through the radiator 30 is hardly obstructed. Therefore, the cooling effect of the radiator 30 on the refrigerant 62 is improved, and the cooling performance for cooling the electronic component 71 is improved. The heat generating component cooled by the cold plate 10 may be other than the electronic component.

### Modification

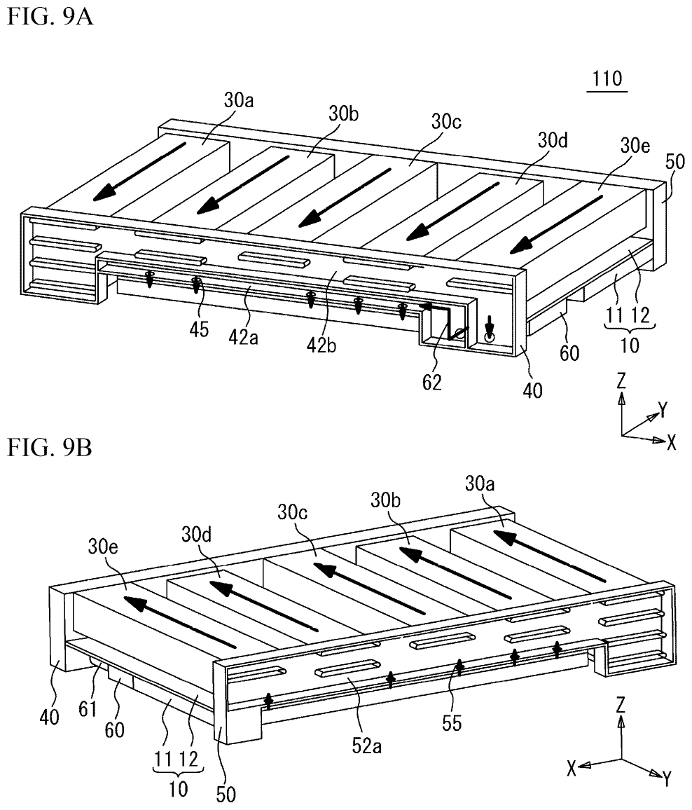

A modification is an example in which the flow of the refrigerant 62 is different from that in the first embodiment. FIGS. 9A and 9B are perspective views illustrating the flow of the refrigerant 62 in a cooling device 110 according to a first modification of the first embodiment. FIG. 9A is a perspective view of the cooling device 110 according to the first modification of the first embodiment as viewed from the −Y direction, and FIG. 9B is a perspective view of the cooling device 110 according to the first modification of the first embodiment as viewed from the +Y direction. As illustrated in FIGS. 9A and 9B, in the first modification of the first embodiment, the interior of the first manifold 40 is divided into a space 42a and a space 42b. The interior of the second manifold 50 is a single space 52a.

The refrigerant 62 discharged from the pump 60 flows into the space 42a of the first manifold 40. The space 42a is provided with the plurality of through holes 45 communicating with the one ends 17 of the plurality of flow paths 14 of the cold plate 10. The plurality of through holes 55 communicating with the other ends 18 of the plurality of flow paths 14 of the cold plate 10 are provided in the space 52a of the second manifold 50. Therefore, the refrigerant 62 flows from the space 42a of the first manifold 40 into the space 52a of the second manifold 50 through the plurality of flow paths 14 of the cold plate 10.

One end of each of the pipes of the plurality of radiators 30a to 30e is connected to the space 52a of the second manifold 50. The other end of each of the pipes of the plurality of radiators 30a to 30e is connected to the space 42b of the first manifold 40. Therefore, the refrigerant 62 flows from the space 52a of the second manifold 50 through the plurality of radiators 30a to 30e in the −Y direction and flows into the space 42b of the first manifold 40.

The refrigerant 62 flowing into the space 42b of the first manifold 40 is sucked into the pump 60. The refrigerant 62 sucked into the pump 60 is discharged from the pump 60 again and flows into the space 42a of the first manifold 40. In this manner, the refrigerant 62 circulates between the first manifold 40, the cold plate 10, the second manifold 50, and the plurality of radiators 30a to 30e.

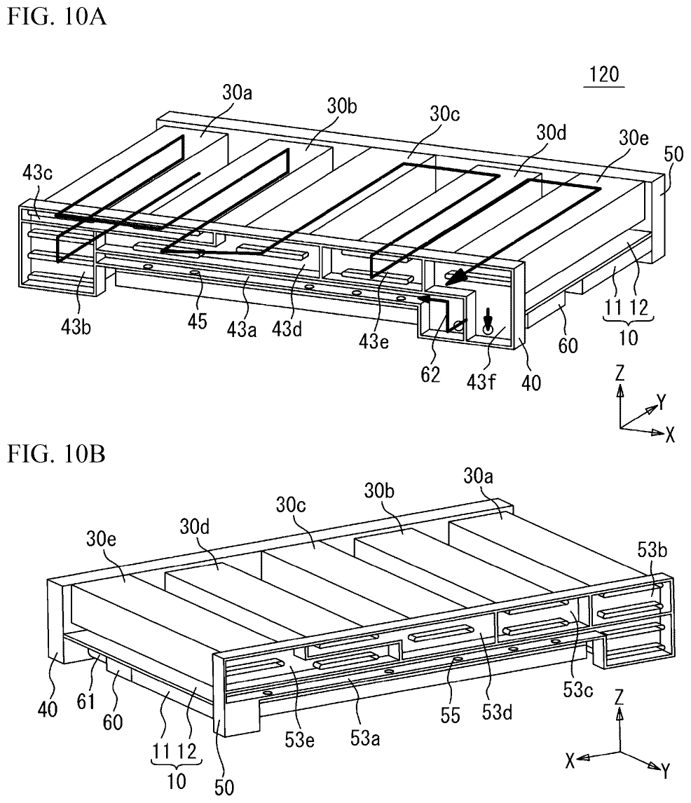

FIGS. 10A and 10B are perspective views illustrating the flow of the refrigerant 62 in a cooling device 120 according to a second modification of the first embodiment. FIG. 10A is a perspective view of the cooling device 120 according to the second modification of the first embodiment as viewed from the −Y direction, and FIG. 10B is a perspective view of the cooling device 120 according to the second modification of the first embodiment as viewed from the +Y direction. In the second modification of the first embodiment, for the sake of clarity, the arrows indicating the flow of the refrigerant 62 are illustrated only in FIG. 10A. As illustrated in FIGS. 10A and 10B, in the second modification of the first embodiment, the interior of the first manifold 40 is divided into a space 43a, a space 43b, a space 43c, a space 43d, a space 43e, and a space 43f. The interior of the second manifold 50 is divided into a space 53a, a space 53b, a space 53c, a space 53d, and a space 53e.

The refrigerant 62 discharged by the pump 60 flows into the space 43a of the first manifold 40. The space 43a is provided with the plurality of through holes 45 communicating with the one ends 17 of the plurality of flow paths 14 of the cold plate 10. The plurality of through holes 55 communicating with the other ends 18 of the plurality of flow paths 14 of the cold plate 10 are provided in the space 53a of the second manifold 50. Therefore, the refrigerant 62 flows from the space 43a of the first manifold 40 into the space 53a of the second manifold 50 through the plurality of flow paths 14 of the cold plate 10.

The space 53a of the second manifold 50 is connected to one ends of the lowermost and the second lowermost pipes of the radiator 30a. The other ends of the lowermost and the second lowermost pipes of the radiator 30a are connected to the space 43b of the first manifold 40. The space 43b is further connected to one end of a second uppermost pipe of the radiator 30a. The other end of the second uppermost pipe of the radiator 30a is connected to the space 53b of the second manifold 50. One end of the uppermost pipe of the radiator 30a is further connected to the space 53b. The other end of the uppermost pipe of the radiator 30a is connected to the space 43c of the first manifold 40. Therefore, the refrigerant 62 flows through the lowermost and the second lowermost pipes of the radiator 30a in the −Y direction, and then flows through the second uppermost pipe of the radiator 30a in the +Y direction. Thereafter, the refrigerant 62 flows through the uppermost pipe of the radiator 30a in the −Y direction and flows into the space 43c of the first manifold 40.

One end of an upper pipe of the radiator 30b is further connected to the space 43c of the first manifold 40. The other end of the upper pipe of the radiator 30b is connected to the space 53c of the second manifold 50. One end of a lower pipe of the radiator 30b is further connected to the space 53c. The other end of the lower pipe of the radiator 30b is connected to the space 43d of the first manifold 40. Therefore, the refrigerant 62 flows through the upper pipe of the radiator 30b in the +Y direction, and then flows through the lower pipe of the radiator 30b in the −Y direction to flow into the space 43d of the first manifold 40.

One end of the pipe of the radiator 30c is further connected to the space 43d of the first manifold 40. The other end of the pipe of the radiator 30c is connected to the space 53d of the second manifold 50. Therefore, the refrigerant 62 flows in the +Y direction through the radiator 30c and flows into the space 53d of the second manifold 50.

One end of an upper pipe of the radiator 30d is further connected to the space 53d of the second manifold 50. The other end of the upper pipe of the radiator 30d is connected to the space 43e of the first manifold 40. One end of a lower pipe of the radiator 30d is further connected to the space 43e. The other end of the lower side pipe of the radiator 30d is connected to the space 53e of the second manifold 50. Therefore, the refrigerant 62 flows through the radiator 30d in the −Y direction, and then flows in the +Y direction into the space 53e of the second manifold 50.

One end of the pipe of the radiator 30e is further connected to the space 53e of the second manifold 50. The other end of the pipe of the radiator 30e is connected to the space 43f of the first manifold 40. Therefore, the refrigerant 62 flows through the radiator 30e in the −Y direction and flows into the space 43f of the first manifold 40.

The refrigerant 62 flowing into the space 43f of the first manifold 40 is sucked into the pump 60. The refrigerant 62 sucked into the pump 60 is discharged from the pump 60 again and flows into the space 43a of the first manifold 40. In this manner, the refrigerant 62 circulates between the first manifold 40, the cold plate 10, the second manifold 50, and the plurality of radiators 30a to 30e.

Although the first embodiment and the modification thereof have described a case where five radiators 30 are provided, the number of radiators 30 is not limited to this case, and one or more radiators 30 may be provided.

As described above, according to the first embodiment and the modification thereof, the radiators 30 for cooling the refrigerant 62 discharged from the plurality of flow paths 14 are provided on the cold plate 10 having the plurality of flow paths 14. The first manifold 40 and the second manifold 50 are provided with the radiators 30 interposed therebetween in the Y-axis direction (first direction). The first manifold 40 allows the refrigerant 62 to flow into the one ends 17 of the flow paths 14, and allows the refrigerant 62 that has passed through the radiators 30 to flow therein. The second manifold 50 allows the refrigerant 62 discharged from the other ends 18 of the flow paths 14 to flow into the radiators 30. As a result, the refrigerant 62 flows between the first manifold 40, the cold plate 10, the second manifold 50, and the radiators 30. Since the radiators 30 are only provided on the cold plate 10, the flow of the wind 73 passing through the radiators 30 is hardly obstructed as described with reference to FIGS. 7A to 8B, and the cooling effect of the refrigerant 62 by the radiators 30 is improved. Therefore, the cooling performance for cooling the electronic component 71 can be improved.

Further, since the pipes 93 are not provided as in the first and the second comparative examples, a mountable region of the radiators 30 can be increased. In this respect, the cooling performance for cooling the electronic component 71 can be improved. Further, since the degree of freedom in designing the flow paths 14 of the cold plate 10 is increased, the degree of freedom in arranging the electronic components 71 can be improved.

In the first embodiment and modification thereof, the plurality of radiators 30 are arranged in the X-axis direction (second direction) on the cold plate 10. The refrigerant 62 flows through the plurality of radiators 30. This improves the cooling effect of the radiators 30 on the refrigerant 62, and thus improves the cooling performance for cooling the electronic component 71.

In the first embodiment, as illustrated in FIGS. 3A and 3B, the refrigerant 62 flows alternately through the plurality of radiators 30a to 30e arranged in the X-axis direction via the first manifold 40 and the second manifold 50. This makes it possible to improve the cooling effect of the radiators 30 on the refrigerant 62.

In the first modification of the first embodiment, as illustrated in FIGS. 9A and 9B, the refrigerant 62 flows through the radiators 30a to 30e in parallel in the −Y direction. In such a case, the structure of the internal space of the first manifold 40 and the second manifold 50 can be simplified.

In the second modification of the first embodiment, as illustrated in FIGS. 10A and 10B, the refrigerant 62 flows alternately in the −Y direction and the +Y direction in the respective radiators 30a, 30b, and 30d via the first manifold 40 and the second manifold 50. This makes it possible to improve the cooling effect of the radiators 30 on the refrigerant 62. FIGS. 10A and 10B illustrate a case where the refrigerant 62 flows alternately in the −Y direction and the +Y direction in the radiators 30a, 30b, and 30d. However, the present disclosure is not limited to this case, and the refrigerant 62 may flow alternately in the −Y direction and the +Y direction in at least one of the plurality of radiators 30a to 30e.

In the first embodiment and modification thereof, a pump capable of switching the directions of suction and discharge of the refrigerant 62 may be used as the pump 60. That is, in FIG. 3A, the pump 60 is not limited to the case where the pump 60 sucks the refrigerant 62 from the space 41d of the first manifold 40 and discharges the refrigerant 62 to the space 41a of the first manifold 40. The pump 60 may also be configured to suck the refrigerant 62 from the space 41a of the first manifold 40 and discharge the refrigerant 62 to the space 41d of the first manifold 40.

The effect of the pump 60 being capable of switching between the suction and discharge directions will be described with reference to the following simulation.

### [Simulation]

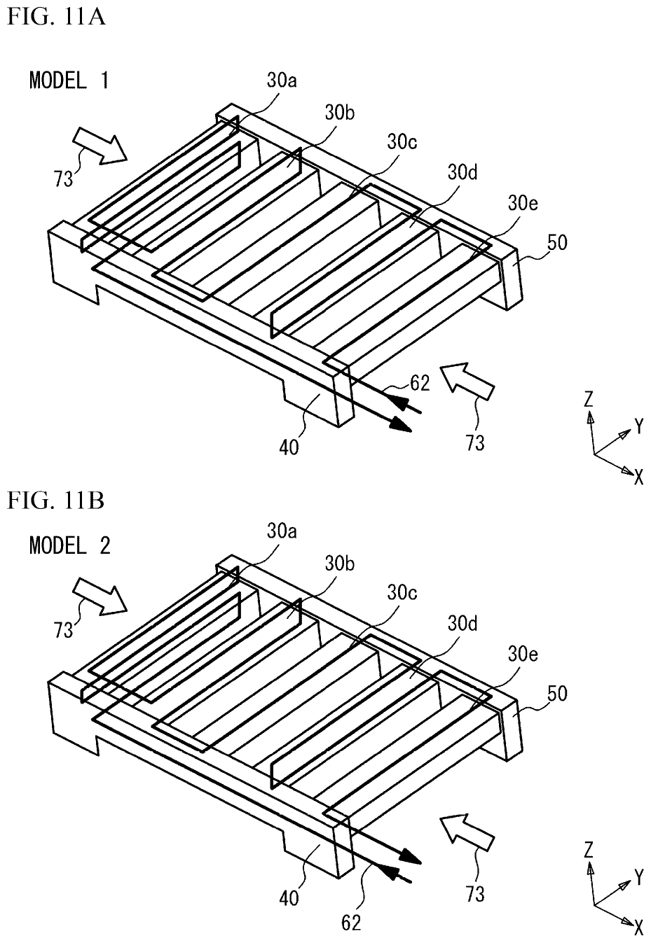

FIGS. 11A and 11B are perspective views of the models 1 and 2 used in simulation. As illustrated in FIGS. 11A and 11B, each of the model 1 and the model 2 is provided with the radiators 30a to 30e arranged in the X-axis direction. The first manifold 40 and the second manifold 50 are provided with the radiators 30a to 30e interposed therebetween in the Y-axis direction. In the model 1, as illustrated in FIG. 11A, the refrigerant 62 flowing into the first manifold 40 flows in the −X direction through the radiator 30e, the radiator 30d, the radiator 30c, the radiator 30b, and the radiator 30a in this order. Thereafter, the refrigerant 62 flows through the first manifold 40 in the +X direction and flows out to the outside. In the model 2, the flow of the refrigerant 62 is reversed from that of the model 1 as illustrated in FIG. 11B. That is, the refrigerant 62 flowing into the first manifold 40 flows in the −X direction through the first manifold 40 and flows into the radiator 30a located on an end in the −X direction. Thereafter, the refrigerant 62 flows in the +X direction through the radiator 30a, the radiator 30b, the radiator 30c, the radiator 30d, and the radiator 30e in this order, and then flows out of the first manifold 40.

The simulation was performed on the difference in temperature of the refrigerant 62 flowing out from the first manifold 40 to the outside when the direction of the wind 73 passing through the radiators 30a to 30e was changed to the +X direction or the −X direction, with respect to the models 1 and 2. In the simulation, the temperature of the refrigerant 62 flowing into the first manifold 40 was fixed at 60° C.

Table 1 indicates simulation results.

TABLE 1

| | | TEMPERATURE OF REFRIGERANT [° C.] | | |
|---|---|---|---|---|
| | WIND | DURING | DURING | DURING INFLOW - |
| | DIRECTION | INFLOW | OUTFLOW | DURING OUTFLOW |
| MODEL 1 | +X DIRECTION | 60 | 46 | 14 |
| | −X DIRECTION | 60 | 49 | 11 |
| MODEL 2 | +X DIRECTION | 60 | 49 | 11 |
| | −X DIRECTION | 60 | 46 | 14 |

As illustrated in Table 1, in the model 1, when the wind 73 was blowing in the +X direction, the temperature of the refrigerant 62 when it flowed out of the first manifold 40 was 46° C. When the wind 73 was blowing in the −X direction, the temperature of the refrigerant 62 when it flowed out of the first manifold 40 was 49° C. Accordingly, in the model 1, the cooling effect of the radiator 30a to 30e on the refrigerant 62 is more enhanced when the wind 73 blows in the +X direction.

In the model 2, when the wind 73 was blowing in the +X direction, the temperature of the refrigerant 62 when it flowed out of the first manifold 40 was 49° C. When the wind 73 was blowing in the −X direction, the temperature of the refrigerant 62 when it flowed out of the first manifold 40 was 46° C. Accordingly, in the model 2, the cooling effect of the radiator 30a to 30e on the refrigerant 62 is more enhanced when the wind 73 is blowing in the −X direction.

The reason why the cooling effect of the radiator 30a to 30e on the refrigerant 62 is enhanced when the wind 73 is blowing in the +X direction in the model 1 and is enhanced when the wind 73 is blowing in the −X direction in the model 2 is considered to be as follows. That is, in the model 1, since the refrigerant 62 supplied to the first manifold 40 flows through the radiator 30e first, the temperature of the refrigerant 62 in the radiator 30e is substantially the temperature of 60° C. when the refrigerant 62 flows into the first manifold 40. When the wind 73 is blowing in the −X direction, the wind 73 first hits the radiator 30e through which the refrigerant 62 having a relatively high temperature flows. Therefore, it is considered that the wind 73 is likely to be warmed, and the cooling effect of the refrigerant 62 in the radiators 30a to 30d after that is weakened. On the other hand, when the wind 73 blows in the +X direction, the wind 73 first hits the radiator 30a through which the refrigerant 62 flows after passing through the radiators 30b to 30e, and thus the wind 73 is hard to be warmed. From the above, it is considered that in the model 1, when the wind 73 blows in the +X direction, the cooling effect of the refrigerant 62 is enhanced as compared with the case where the wind 73 blows in the −X direction. The same is true for the model 2. Accordingly, for example, in the case where the refrigerant 62 flows as illustrated in FIGS. 3A and 3B, it is preferable that the wind 73 blows in the −X direction.

From the simulation results, in the first embodiment and the modification thereof, from the viewpoint of enhancing the cooling effect of the refrigerant 62 by the radiators 30, it is preferable that the flow of the refrigerant 62 can be reversed in accordance with the direction of the wind 73 passing through the radiators 30. The direction of the wind 73 may vary depending on the electronic apparatus including the cooling device in the first embodiment and the modification thereof. For example, when the cooling device of the present disclosure is applied to a LAN card or the like connected to a personal computer, the radiators 30 are cooled by a fan attached to the personal computer. In this case, the direction in which the wind 73 from the fan blows toward the radiators 30 may vary depending on the type of personal computer or the like. Accordingly, in view of such a case, it is preferable to use the pump 60 capable of switching the directions of suction and discharge of the refrigerant 62 from the viewpoint of enhancing the cooling effect of the refrigerant 62 by the radiators 30. The pump 60 may include a sensor for detecting the direction of the wind 73, and may switch the directions of suction and discharge of the refrigerant 62 in accordance with information from the sensor.

Instead of using the pump 60 capable of switching the directions of suction and discharge of the refrigerant 62, a combination of the first and second manifolds 40 and 50 and the radiator 30 is separately prepared so that the direction of the refrigerant 62 flowing through the radiator 30 is opposite. The original combination thereof may be replaced with the prepared combination of the first and second manifolds 40 and 50 and the radiator 30, which allows the flow of the refrigerant 62 to be in an appropriate direction depending on the direction of the wind 73.

### Second Embodiment

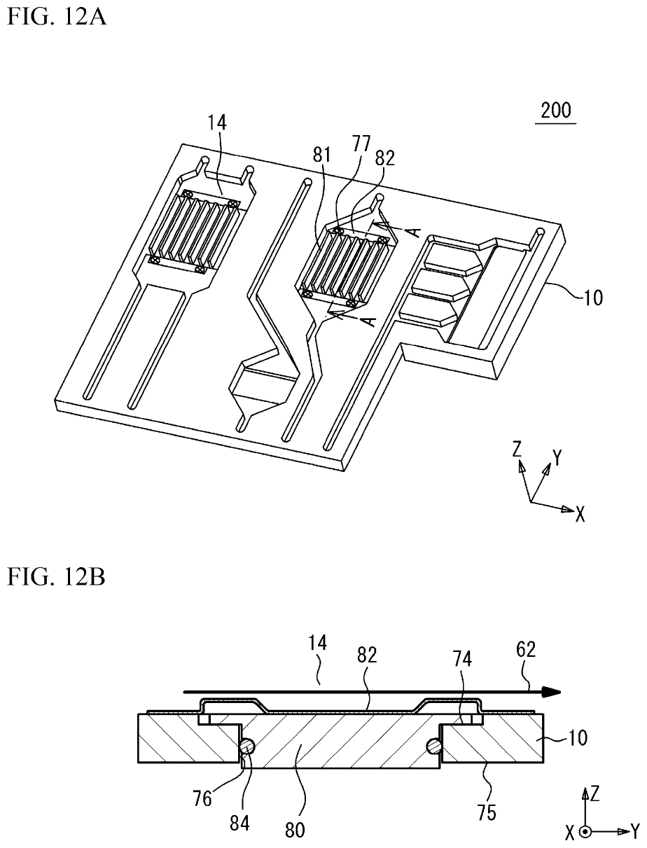

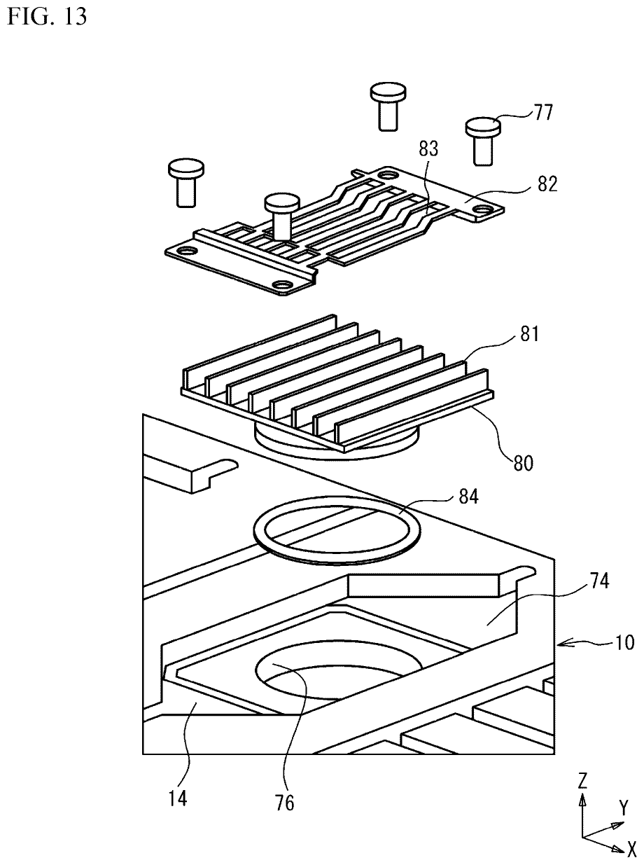

FIG. 12A is a perspective view of the cold plate 10 of a cooling device 200 according to a second embodiment, and FIG. 12B is a cross-sectional view taken along a line A-A in FIG. 12A. FIG. 13 is an exploded perspective view of an insertion member 80, a pressing member 82, and an elastic member 84 in the second embodiment. As illustrated in FIGS. 12A, 12B and 13, in the second embodiment, the cold plate 10 has a through hole 76 penetrating a lower surface 75 of the cold plate 10 on a bottom surface 74 of at least one of the plurality of flow paths 14. The insertion member 80 is provided on the bottom surface 74 of the flow path 14. A part of the insertion member 80 is inserted into the through hole 76 so as to be movable in the depth direction with respect to the through hole 76. The insertion member 80 is formed of a material having a high thermal conductivity, for example, a metal such as copper, silver, gold, or aluminum. The insertion member 80 has a plurality of fins 81 projecting into the flow path 14.

The pressing member 82 for pressing the insertion member 80 toward the through hole 76 is provided on the bottom surface 74 of the flow path 14. The pressing member 82 is, for example, a plate spring, and four corners thereof are fixed to the bottom surface 74 of the flow path 14 by fixing members 77 such as screws. The pressing member 82 has a plurality of holes 83 into which the plurality of fins 81 of the insertion member 80 are inserted. The pressing member 82 is not limited to the plate spring, and may be any other member such as a coil spring as long as it can press the insertion member 80. The annular elastic member 84 is provided between the side wall of the through hole 76 and the insertion member 80. The elastic member 84 is, for example, an O-ring.

The refrigerant 62 flowing through the flow path 14 flows over the insertion member 80 and the pressing member 82. Therefore, the fins 81 of the insertion member 80 are in contact with the refrigerant 62. The elastic member 84 provided between the side wall of the through hole 76 and the insertion member 80 suppresses the refrigerant 62 from leaking downward from the through hole 76. The other components are the same as those of the first embodiment, and therefore, the description thereof is omitted.

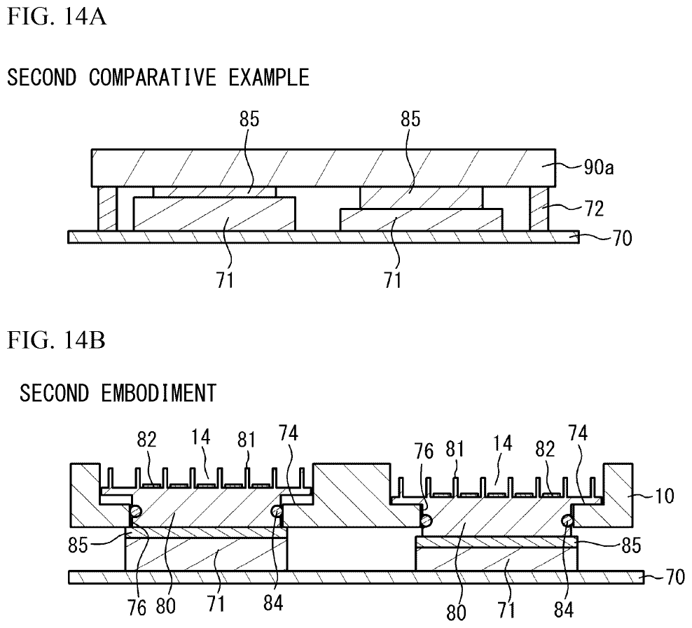

FIG. 14A is a cross-sectional view illustrating a problem occurring in the cooling device according to the second comparative example. As illustrated in FIG. 14A, in order to efficiently transfer heat generated in the electronic components 71 to the cold plate 90a, heat conductive sheets 85 such as TIM (Thermal Interface Material) may be disposed between the electronic components 71 and the cold plate 90a. The heat conductive sheets 85 are made of resin such as silicone or epoxy, and filled with a high thermal conductive filler therein. On the other hand, the electronic components 71 have variations in height. Examples of the variations are manufacturing tolerances and differences in product type. If the electronic components 71 have different heights, one of the heat conductive sheets 85 located between the electronic component 71 having a low height and the cold plate 90a becomes thick in the case where the cold plate 90a of the integral type is used. Although the one of the heat conductive sheets 85 is provided to efficiently conduct heat generated in the electronic component 71 to the cold plate 90a, the heat conduction is difficult to conduct when the one of the heat conductive sheets 85 is thick, and the cooling performance for cooling the electronic component 71 is lowered.

FIG. 14B is a cross-sectional view illustrating the effect of the cooling device 200 according to the second embodiment. As illustrated in FIG. 14B, the insertion members 80 are inserted into the through holes 76 provided in the bottom surfaces 74 of the flow paths 14 so as to be movable in the depth direction with respect to the through holes 76, respectively. The insertion members 80 are pressed toward the through holes 76 by the pressing members 82. Therefore, even if the electronic components 71 have variations in height, the variations in height of the electronic components 71 can be absorbed by the movement of the insertion members 80, and the thickness of each of the heat conductive sheets 85 can be set to an appropriate thickness. Accordingly, heat generated in the electronic components 71 is efficiently conducted to the cold plate 10 through the heat conductive sheets 85, and the cooling performance for cooling the electronic components 71 is improved.

As described above, according to the second embodiment, the cold plate 10 has the through hole 76 penetrating the cold plate 10 on the bottom surface 74 of at least one of the plurality of flow paths 14. The insertion members 80 are inserted into the through holes 76 so as to be movable in the depth direction with respect to the through holes 76. The pressing members 82 for pressing the insertion members 80 toward the through holes 76 are provided on the insertion members 80. As a result, as described with reference to FIG. 14B, it is possible to absorb the variation in the height of the electronic components 71. Accordingly, heat generated in the electronic components 71 is efficiently conducted to the cold plate 10 through the heat conductive sheets 85, and the cooling performance for cooling the electronic components 71 can be improved.

In the second embodiment, each of the insertion members 80 includes fins 81 projecting into the flow path 14. This allows efficient heat exchange between the refrigerant 62 flowing through the flow paths 14 and the electronic components 71 via the insertion members 80, and improves the cooling performance for cooling the electronic components 71.

### Third Embodiment

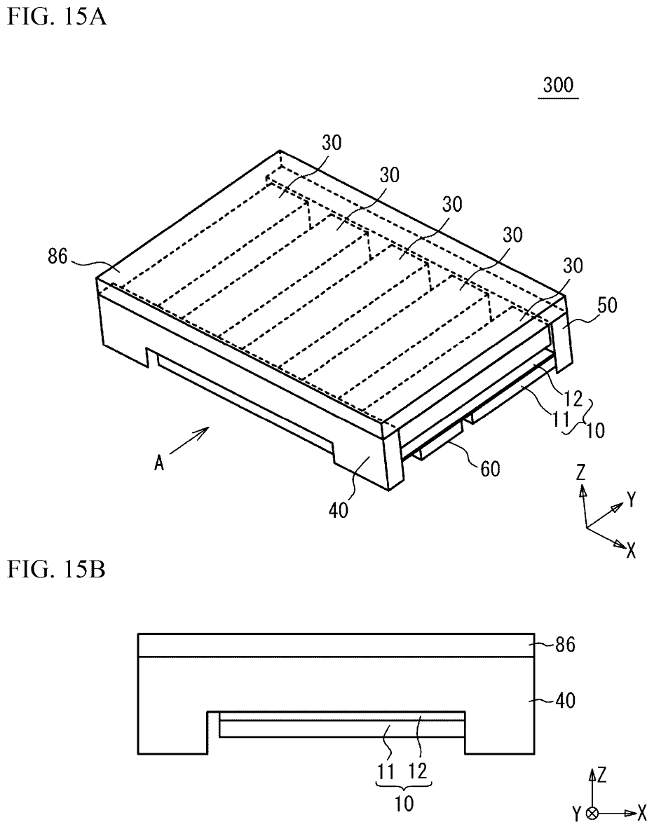

FIG. 15A is a perspective view of a cooling device 300 according to a third embodiment, and FIG. 15B is a side view of the cooling device 300 as viewed from a direction A in FIG. 15A. As illustrated in FIGS. 15A and 15B, in the third embodiment, a plate-shaped cover member 86 is provided on the first manifold 40 and the second manifold 50 to cover the plurality of radiators 30. The cover member 86 may be a metal member or an insulating member. The other components are the same as those of the first embodiment, and therefore, the description thereof is omitted.

According to the third embodiment, the plate-shaped cover member 86 is provided on the first manifold 40 and the second manifold 50 so as to interpose the plurality of radiators 30 between the plate-shaped cover member 86 and the cold plate 10. As a result, a space surrounded by the cold plate 10, the cover member 86, the first manifold 40 and the second manifold 50 functions as a tube (duct) for carrying air. Since the radiators 30 are disposed in this space, the wind 73 can be efficiently flown to the radiators 30, and the cooling effect of the refrigerant 62 by the radiators 30 can be improved.

### Fourth Embodiment

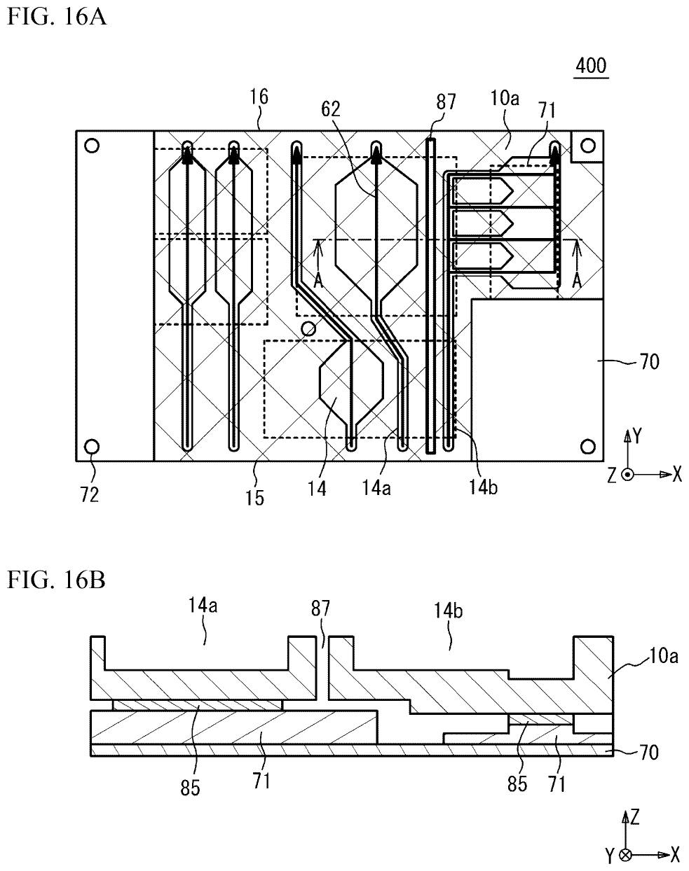

FIG. 16A is a plan view of the substrate 70 on which a cooling device 400 according to the fourth embodiment is mounted, and FIG. 16B is a cross-sectional view taken along a line A-A in FIG. 16A. FIG. 16A illustrates the electronic components 71 provided on the substrate 70 and a cold plate 10a in the fourth embodiment. As illustrated in FIGS. 16A and 16B, in the fourth embodiment, the cold plate 10a is provided with a slit 87 between a flow path 14a and a flow path 14b. The slit 87 extends from the side wall 15 of the cold plate 10a toward the side wall 16 and penetrates the cold plate 10a. The refrigerant 62 does not flow through the slit 87. The slit 87 is preferably provided between the electronic component 71 having the smallest allowable temperature in the plurality of electronic components 71 and the adjacent electronic component 71. Alternatively, the slit 87 is preferably provided between the electronic component 71 having the largest heat generation amount in the plurality of electronic components 71 and the adjacent electronic component 71. The other components are the same as those of the first embodiment, and therefore, the description thereof is omitted.

According to the fourth embodiment, the cold plate 10a has the slit 87 through which the refrigerant 62 does not flow between two of the flow paths 14a and 14b. This can suppress the heat transfer between the electronic component 71 cooled by the refrigerant 62 flowing through the flow path 14a and the electronic component 71 cooled by the refrigerant 62 flowing through the flow path 14b via the cold plate 10a. The slit 87 preferably penetrates the cold plate 10a, but may be a groove dug in a depth equal to or greater than half the depth of the cold plate 10a, or a groove dug in a depth equal to or greater than three quarters the depth of the cold plate 10a. The slit 87 may be divided at a part in the Y-axis direction. From the viewpoint of suppressing the heat transfer between the electronic components 71, the total length of the slit 87 in the Y-axis direction is preferably 50% or more, more preferably 70% or more, and still more preferably 90% or more an interval between the side walls 15 and 16 of the cold plate 10a facing each other in the Y-axis direction.

### Fifth Embodiment

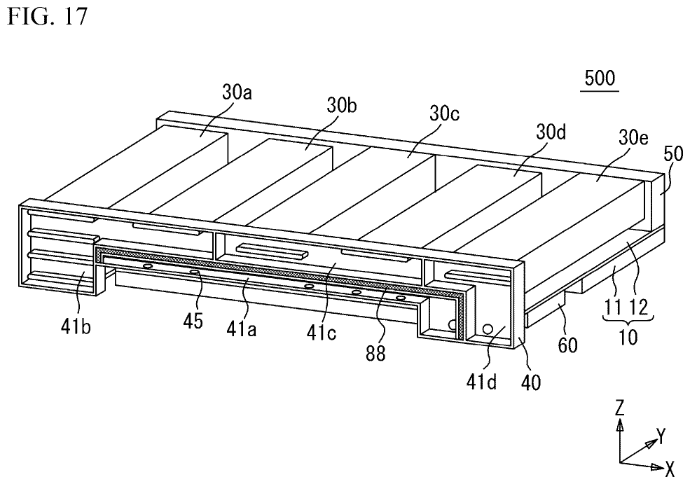

FIG. 17 is a perspective view of a cooling device 500 according to a fifth embodiment. As illustrated in FIG. 17, in the fifth embodiment, the first manifold 40 has a heat insulating portion 88 between the space 41a and the spaces 41b, 41c, and 41d. The heat insulating portion 88 is formed of a material or an air layer having a thermal conductivity smaller than that of the other portions of the first manifold 40. For example, the heat insulating portion 88 is formed of a material such as urethane or cellulose fiber, or an air layer or a vacuum layer. The other components are the same as those of the first embodiment, and therefore, the description thereof is omitted.

According to the fifth embodiment, the first manifold 40 is provided with the heat insulating portion 88 between the space 41a (first space) and the space 41b (second space). The space 41a (first space) is a space through which the refrigerant 62 flows before being supplied to the flow path 14 of the cold plate 10 (see FIG. 3A). The space 41b (second space) is a space in which the refrigerant 62 flows after flowing through the flow path 14 of the cold plate 10 (see FIG. 3A). Therefore, there is a temperature difference between the refrigerant 62 flowing through the space 41a and the refrigerant 62 flowing through the space 41b. Therefore, when the heat insulating portion 88 is not provided between the space 41a and the space 41b, the temperature of the refrigerant 62 flowing through the space 41a may be increased by the refrigerant 62 flowing through the space 41b. In this case, the cooling performance for cooling the electronic component 71 is lowered. On the other hand, since the heat insulating portion 88 is provided between the space 41a and the space 41b, the temperature of the refrigerant 62 flowing through the space 41a is suppressed from increasing, and therefore, the cooling performance for cooling the electronic component 71 is suppressed from being lowered.

In the fifth embodiment, from the viewpoint of suppressing a temperature rise of the refrigerant 62 flowing through the space 41a, the heat insulating portion 88 is preferably provided in 80% or more of a region where the space 41a and the space 41b are adjacent to each other. The heat insulating portion 88 is more preferably provided in 90% or more of the region, and most preferably provided in all of the region. The same applies to the space 41a and the space 41c. The length of the heat insulating portion 88 between the space 41a and the space 41b is about 2 mm, for example, 1 mm or more and 3 mm or less, or 1.5 mm or more and 2.5 mm or less.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A cooling device comprising:
a cold plate that includes a plurality of flow paths through which a refrigerant flows, and cools a heat generating component with the refrigerant, one ends of the plurality of flow paths being positioned near one side wall of a pair of side walls in a first direction, and the other ends thereof being positioned near the other side wall;
a radiator that is provided on the cold plate and cools the refrigerant to be discharged from the plurality of flow paths; and
a first manifold and a second manifold that are provided with the radiator interposed therebetween in the first direction;
wherein the first manifold allows the refrigerant to flow into the one ends of the plurality of flow paths and allows the refrigerant having passed through the radiator to flow therein, and
the second manifold allows the refrigerant discharged from the other ends of the plurality of flow paths to flow into the radiator.

2. The cooling device according to claim 1, wherein
the radiator includes a plurality of radiators that are provided on the cold plate and cool the refrigerant to be discharged from the plurality of flow paths,
the plurality of the radiators are arranged on the cold plate in a second direction intersecting the first direction, and
the refrigerant flows through the plurality of radiators.

3. The cooling device according to claim 2, wherein
the refrigerant flows through the plurality of radiators arranged in the second direction in alternating directions via the first manifold and the second manifold.

4. The cooling device according to claim 2, wherein
the refrigerant flows alternately in a first orientation and a second orientation opposite to the first orientation in at least one of the plurality of radiators via the first manifold and the second manifold.

5. The cooling device according to claim 2, wherein
the refrigerant flows in parallel in one orientation through the plurality of radiators.

6. The cooling device according to claim 1, wherein
the cold plate has a through hole penetrating the cold plate on a bottom surface of at least one of the plurality of flow paths,
the cooling device further comprising:
an insertion member that is movable in the depth direction with respect to the through hole and is inserted into the through hole; and
a pressing member that is provided on the insertion member and presses the insertion member toward the through hole.

7. The cooling device according to claim 6, wherein
the insertion member includes fins projecting into the at least one of the plurality of flow paths.

8. The cooling device according to claim 6, further comprising:
an annular elastic member provided between a side wall of the through hole and the insertion member.

9. The cooling device according to claim 1, further comprising:
a pump that sucks the refrigerant discharged from the radiator and discharges the refrigerant to the first manifold,
wherein the pump is capable of switching a direction of suction and discharge of the refrigerant.

10. The cooling device according to claim 9, wherein
the cold plate has a notch, and the pump is provided in the notch of the cold plate.

11. The cooling device according to claim 1, further comprising:
a plate-shaped cover member provided on the first manifold and the second manifold so as to interpose the radiator between the cold plate and the plate-shaped cover member.

12. The cooling device according to claim 1, wherein
the cold plate has a slit through which the refrigerant does not flow between two of the plurality of flow paths.

13. The cooling device according to claim 1, wherein
the first manifold includes a first space in which the refrigerant flows before being supplied to one ends of the plurality of flow paths, a second space in which the refrigerant flows after flowing through the plurality of flow paths, and a heat insulating portion provided between the first space and the second space.

14. The cooling device according to claim 1, wherein
the refrigerant flows from the first manifold into the plurality of flow paths through first through holes provided in the first manifold, and is discharged from the plurality of flow paths into the second manifold through second through holes provided in the second manifold.

15. An electronic apparatus comprising:
an electronic component;
a cooling device that cools the electronic component;
the cooling device includes:
a cold plate that includes a plurality of flow paths through which a refrigerant flows, and cools a heat generating component with the refrigerant, one ends of the plurality of flow paths being positioned near one side wall of a pair of side walls in a first direction, and the other ends thereof being positioned near the other side wall;
a radiator that is provided on the cold plate and cools the refrigerant to be discharged from the plurality of flow paths; and
a first manifold and a second manifold that are provided with the radiator interposed therebetween in the first direction;
wherein the first manifold allows the refrigerant to flow into the one ends of the plurality of flow paths and allows the refrigerant having passed through the radiator to flow therein, and
the second manifold allows the refrigerant discharged from the other ends of the plurality of flow paths to flow into the radiator.
